(19) United States
(12) Patent Application Publication
(10) Pub. No.: US 2007/0176303 A1
(43) Pub. Date: Aug. 2, 2007

(54) Circuit device

(76) Inventors: Makoto Murai, Isehara-City (JP); Ryosuke Usui, Ichinomiya-City (JP); Tetsuro Sawai, Hashima-City (JP); Toshikazu Imaoka, Ogaki-City (JP); Yasunori Inoue, Ogaki-City (JP)

Correspondence Address: MCDERMOTT WILL & EMERY LLP, 600 13TH STREET, N.W., WASHINGTON, DC, 20005-3096, US

(21) Appl. No.: 11/645,803

(22) Filed: Dec. 27, 2006

(30) Foreign Application Priority Data
Dec. 27, 2005 (JP) JP 2005-374215
Dec. 27, 2005 (JP) JP 2005-374217

(51) Int. Cl. H01L 23/28

(52) U.S. Cl. 257/787; 257/E23.124

(57) ABSTRACT

A highly reliable circuit device is provided at low cost. The circuit device includes a semiconductor element electrically connected to a wiring layer (copper plate and plating film) and passive parts sealed by a molded resin layer. The wiring layer has a predetermined pattern formed by a conductive member. The molded resin layer has projections protruding from gaps in the adjacent wiring layer toward an underside of the wiring layer. Thereby, the drop of yield is prevented and the highly reliable circuit device is provided at low cost.

### BACKGROUND OF THE INVENTION

1. Field of the Invention

The present invention relates to a circuit device.

2. Description of the Related Art

As portable electronics equipment, such as mobile phones, PDAs, DVCs and DSCs, feature more and more advanced functions, it is a primary requirement that these products be small-size and lightweight if they are to be well-received on the market. And, along with this trend, highly integrated system LSIs are in ever-greater demand to meet the requirement. On the other hand, such electronics equipment must be handy and easy to use, and accordingly the LSIs used in them need to be highly-functional and of high-performance. As a result, the number of I/Os is increasing in proportion to the higher integration of the LSI chip, and at the same time, there is a strong demand for smaller size for the package itself. To meet these two-fold demands, the development of semiconductor packaging suited to high-density board mounting of semiconductor parts is strongly desired.

Known as a packaging technology that meets such requirement for higher-density packaging is a resin-sealed packaging of leadless surface-mounted type (See Reference (1) in the following Related Art List).

FIG. 14 is a cross-sectional view schematically showing a structure of a conventional circuit device as disclosed in the above-cited Reference (1). In the conventional circuit device as shown in FIG. 14, one end of a bonding wire 103 is bonded to the an electrode pad 102 on a semiconductor element 101, and the other end thereof is bonded to a metal film 105 exposed from the bottom surface of a resin package 104 formed of a molded resin. The metal film 105 and the bottom surface of the resin package are nearly in the same plane. The lower surface (bottom) of the semiconductor element 101 is protected by a die attaching material. The metal film 105 is so configured as to be electrically connected to the semiconductor element 101 by a bonding wire 103. This metal film 105, which functions as an external connection terminal of the circuit device, is soldered to an electrode part formed on a mounting board (not shown) when the circuit device is mounted thereon.

Also known as a packaging technology that meets such requirement for higher-density packaging is a multi-chip module (MCM) which employs a multi-stage stack structure of a plurality of circuit elements.

For an MCM, a requisite to assure an adequate level of production yield is the use of a KGD (Known Good Die) for which the integrity of individual circuit elements is certified. Conventionally, therefore, the circuit devices offered have been ones with the KGD certified by the package having both testing electrodes to prove the KGD and electrodes for connection with the other circuits as disclosed in Reference (2) in the following Related Art List. And such circuit devices have been used to structure MCMs.

Related Art List

(1) Japanese Patent Application Laid-Open No. Hei10-116935.
(2) Japanese Patent Application Laid-Open No. 2002-40095.

Conventional circuit devices are characterized by having the back surface of the metal film 105 and the bottom surface of the resin package 104 formed approximately in the same plane. As a consequence, in the soldering for the formation of solder balls as external electrodes of a circuit device or for the mounting of a circuit device on a mounting board, there have been cases of short-circuiting of wiring of the circuit device due to the solders of the adjacent metal films (external connection terminals) coming into contact with each other. Also, there have been cases of damage to the metal film 105 when, for instance, a circuit device is placed on a stand for the operation test during a manufacturing process and as a result the back surface of the metal film 105 came into direct contact with the stand.

### SUMMARY OF THE INVENTION

The present invention has been made to solve problems as described above, and a general purpose thereof is to provide a highly reliable circuit device at low cost.

In order to resolve the above problems, a circuit device according to one embodiment of the present invention comprises: a wiring layer; a circuit element provided above the wiring layer; and a molded resin layer which seals the circuit element, wherein there are provided projections, made of insulating material, which protrude from gaps in the wiring layer toward an underside of said wiring layer.

According to this embodiment, the projections, made of insulating material, which protrude from the gaps in the wiring layer work as obstacles that prevent the occurrence of migration between the neighboring wiring layers.

At the time when solder balls are formed as external electrodes of a circuit device, or in the soldering when the circuit device is mounted on a mounting board, the projections, made of insulating material, work as obstacles that prevent the solders from coming into contact with each other in the neighboring wiring layers.

The projections support the circuit device when the circuit device is placed on a stand. Thus, when the circuit device is carried on a stand for the operation test during a manufacturing process, the wiring layer is prevented from getting damaged as it comes into contact with the stand.

When the circuit device is mounted on a mounting board using an adhesive layer, the projections bite into the adhesive layer, thus producing an anchor effect. As a result adhesion between the adhesive layer and the circuit device is enhanced.

As a result of these described above, the drop of fabrication yield can be prevented and therefore highly reliable circuit devices can be provided at low cost.

In the above embodiment, the projection may be part of the molded resin layer. According to this embodiment, the structure of a circuit device and the manufacturing process thereof can be simplified and the manufacturing cost of the circuit device can be further reduced.

A circuit device, according to another embodiment of the present invention, further comprise an insulation layer provided between the wiring layer and the circuit element, wherein the projection is part of the insulation layer and the thermal conductivity of the insulation layer is higher than that of the molded resin layer.

According to this embodiment, as for the heat generated from the circuit element, the heat arising in the circuit element is released efficiently by promoting heat diffusion through the insulation layer with higher thermal conductivity as a heat radiation path. Also, the surface area of the insulation layer made larger by the presence of projections improves the heat radiation of the circuit device.

In the above embodiment, it is preferable that the insulation layer includes a particulate filler material, and part of the particulate filler material in the projection of the insulation layer is exposed. As a result, ups and downs are created on the surface of the projections due to the exposed filler material, so that the radiation of the circuit element is further enhanced.

It is to be noted that any arbitrary combination or rearrangement of the above-described structural components and so forth are all effective as and encompassed by the present embodiments.

Moreover, this summary of the invention does not necessarily describe all necessary features so that the invention may also be sub-combination of these described features.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 is a cross-sectional view showing a structure of a circuit board according to a first embodiment of the present invention;

FIGS. 2A to 2D are cross-sectional views showing a process of manufacturing method for a circuit board according to a first embodiment of the present invention;

FIGS. 3A to 3C are cross-sectional views showing a process of manufacturing method for a circuit board according to a first embodiment of the present invention;

FIG. 4 is a cross-sectional view showing a structure of a circuit device according to a second embodiment of the present invention;

FIGS. 5A to 5E are cross-sectional views to explain a manufacturing method for a circuit device according to a second embodiment of the present invention;

FIGS. 6A to 6D are cross-sectional views to explain a manufacturing method for a circuit device according to a second embodiment of the present invention;

FIG. 7 is a top view illustrating a structure of a circuit device according to a third embodiment of the present invention;

FIG. 8 is a bottom view illustrating a structure of a circuit device according to a third embodiment of the present invention.

FIG. 9 is a cross-sectional view taken along the line A-A′ of the circuit device shown in FIG. 7;

FIGS. 10A to 10D are cross-sectional views showing a process of a manufacturing method for a circuit device according to a third embodiment of the present invention;

FIGS. 11A to 11D are cross-sectional views showing a process of a manufacturing method for a circuit device according to a third embodiment of the present invention;

FIG. 12 is a cross-sectional view showing a structure of a circuit module according to a fourth embodiment of the present invention;

FIGS. 13A to 13F are cross-sectional views showing a process of a manufacturing method for a circuit module according to a fourth embodiment of the present invention; and

FIG. 14 is a cross-sectional view schematically showing a structure of a conventional circuit device.

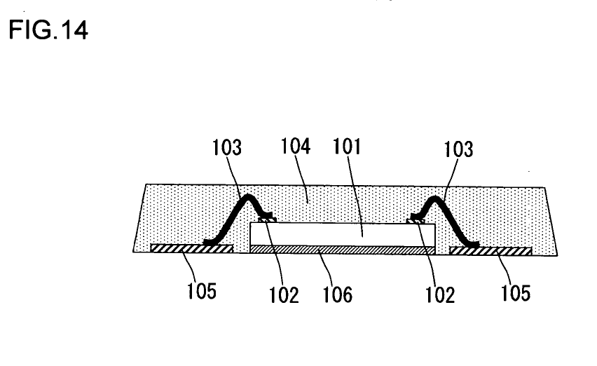

### DETAILED DESCRIPTION OF THE INVENTION

The invention will now be described by reference to the preferred embodiments. This does not intend to limit the scope of the present invention, but to exemplify the invention.

Embodiments of the present invention will now be described in detail with reference to drawings. Note that in all the figures, the same reference numbers are used to indicate the same or similar component elements and the description thereof is omitted as appropriate. In this specification, the “up” direction is a concept determined from the order in which the films are stacked; that is, the “up” direction is where the films stacked later exist as seen from the side of the films stacked earlier.

### FIRST EMBODIMENT

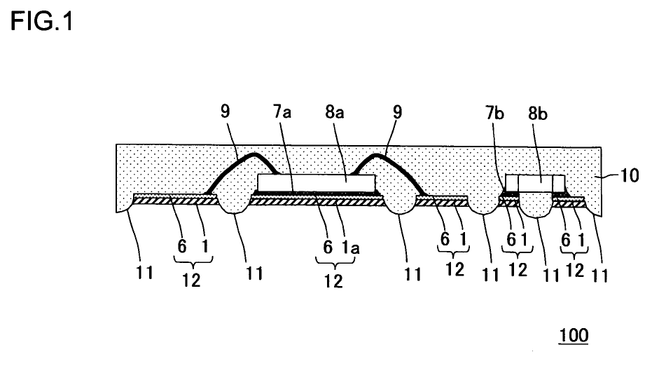

FIG. 1 is a cross-sectional view showing a structure of a circuit device according to a first embodiment of the present invention. A circuit device 100 includes wiring layers 12 (copper plate 1, plating film 6), a semiconductor element 8a, a passive part 8b, and a molded resin layer 10.

A wiring layer 12 has a predetermined pattern formed by a conductive member. The wiring layer 12 may be formed of a single metal such as copper (Cu), but may also be formed of a plurality of metal layers. For example, forming an Au film on top of a copper layer through the medium of a Ni film may improve the connection reliability of wire bonding.

The semiconductor element 8a is a semiconductor chip, such as an IC (integrated circuit) or an LSI (large-scale integration circuit). The semiconductor element 8a is connected to the top of a metal substrate 1a, which is provided approximately in the same plane as the wiring layer 12, via solder 7a. As with the wiring layer 12, the metal substrate 1a may be formed of a single metal such as copper, but may also be formed of a plurality of metal layers. Use of the same layer structure for both the metal substrate la and the wiring layer 12 can simplify the manufacturing process for the circuit device 100. Electrode terminals of the semiconductor element 8a and the wiring layer 12 are wire-bonded to each other via wire 9 such as gold wire.

The passive part 8b is an electronic part, such as a capacitor, resistor, coil, or inductor. The passive part 8b is connected to the top of the wiring layer 12 via solder 7b and is thus electrically connected to the wiring layer 12.

The molded resin layer 10 seals the semiconductor element 8a and the passive part 8b provided above the wiring layer 12, thus protecting them against external influences. The material for the molded resin layer 10 is, for example, a thermosetting insulating resin, such as an epoxy resin. Sealing the semiconductor element 8a and the passive part 8b with the molded resin layer 10 can prevent the semiconductor element 8a and the like from getting broken or damaged at the time of operation test before the circuit device 100 is mounted, for instance. It also prevents changes in characteristics of the semiconductor element 8a and the like caused by the storage environment of the circuit device 100, which makes the market distribution thereof possible unlike the case with bare chips.

The molded resin layer 10 has projections 11, which protrude from the gaps in the wiring layer 12 toward the underside of the wiring layer 12.

The advantageous effects that are realized by the projections 11 include the following:
(1) The projections 11 support the circuit device 100 when the circuit device is placed on a stand. Thus, for instance, when the circuit device is carried on a stand for the operation test during a manufacturing process, it is possible to prevent the wiring layer 12 (copper plates 1 and 1a especially) from getting damaged as it comes into contact with the stand.
(2) When a circuit device 100 is mounted on a circuit module, the projections 11, which are insulators, create a proper gap between the wiring layer 12 and the opposing surface of the circuit module, which will prevent the wiring layer 12 of the circuit device 100 from coming into contact with the other circuit in the circuit module.
(3) When a circuit device 100 is mounted on the other circuit device, a resin substrate, or the like, the projections 11 create increased surface friction, thus making it easier to position the circuit device 100 without unwanted slips.
(4) When a circuit device 100 is mounted on a mounting board or the like using an adhesive layer (not shown), the projections 11 bite into the adhesive layer, thus producing an anchor effect, so that a closer contact may be achieved between the adhesive layer and the circuit device 100.
(5) When a circuit device 100 is mounted on an object, the projections 11, which function as spacers, create a proper gap between the circuit device 100 and the object. As a result, the forces working on the circuit device 100 when it is mounted on the object using an adhesive material will be made even, thus preventing the circuit device 100 from tilting with the adhesive material locally pushed out.
(6) The projections 11, which are insulators, work as obstacles that prevent the occurrence of migration between the wiring layers 12.
(7) When solder balls are formed as external electrodes of a circuit device 100 or when soldering is carried out in the mounting of a circuit device 100 on a mounting board, the projections 11, which are insulators, work as obstacles for solder flow, thus preventing the solders placed between adjacent wiring layers 12 from contacting each other.
(8) When the semiconductor element 8a and the passive part 8b heat up, the resulting thermal expansion of the molded resin layer 10 may increase the stress that works at its interface with the wiring layer 12. However, the separation of the molded resin layer 10 from the wiring layer 12 is prevented by the anchor effect of the projections 11 protruding from the gaps in the wiring layer 12.
(9) When the projections 11 are located at the outermost periphery of the wiring layer 12, the sides (periphery) of the wiring layer 12 are covered by the projections 11. In consequence, even when a shearing stress occurs due to the difference in linear coefficient of expansion between the wiring layer 12 and the molded resin layer 10, the wiring layer 12 is held in by the projections 11 from all sides, so that no separation may occur at the interface between the molded resin layer 10 and the wiring layer 12, thus improving the reliability of bond between the wiring layer 12 and the molded resin layer 10.

As described above, the present embodiment can provide a highly reliable circuit device 100 at low cost because the drop in yield thereof can be held in check.

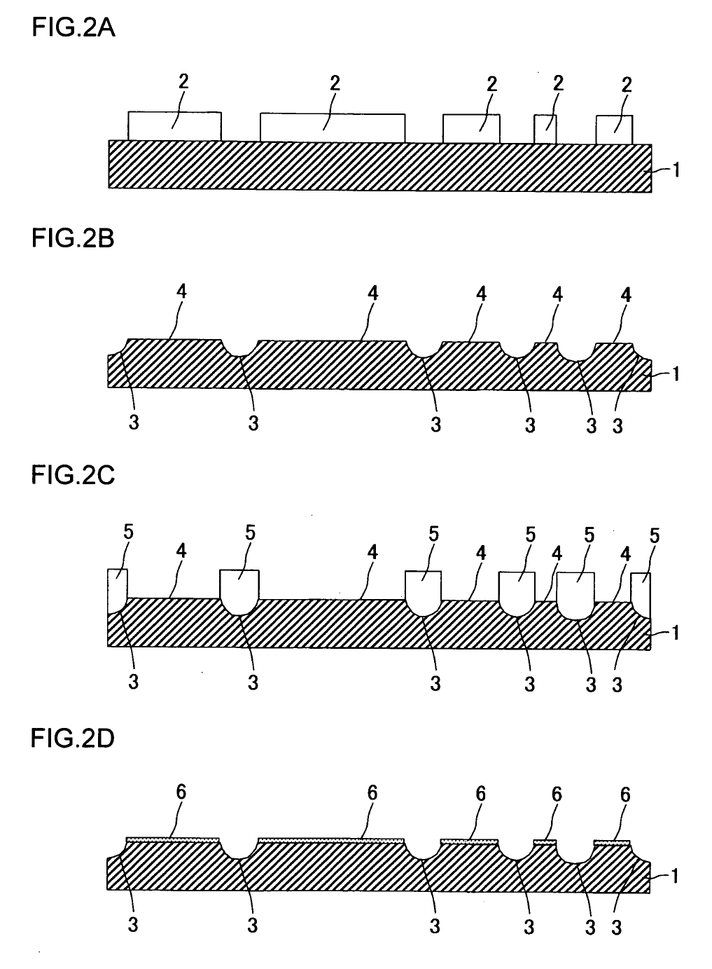

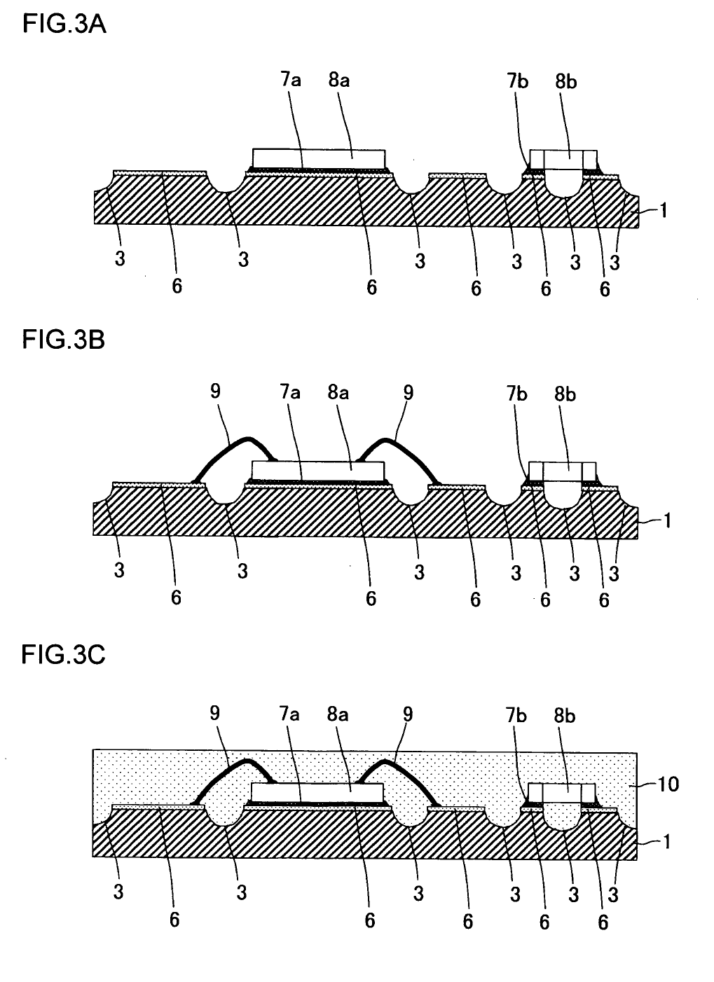

FIGS. 2A to 2D and FIGS. 3A to 3C illustrate a manufacturing method for a circuit device 100 according to the first embodiment.

Firstly, as shown in FIG. 2A, resists 2 are selectively formed according to a pattern of wiring layer on a copper plate 1 by lithography. The film thickness of the copper plate 1 is 125 μm, for instance. More specifically, a resist film of 20 μm thickness is affixed to the copper plate 1 by a laminator unit, and it is then subjected to a UV irradiation using a photo mask having a wiring layer pattern. After this, the resists in the unexposed areas are removed by a development using a Na₂CO₃ solution, which will selectively form resists 2 on the copper plate 1. To improve the adhesion of the resists 2 to the copper plate 1, it is desirable that a pretreatment, such as grinding, cleaning and the like, be performed as appropriate on the surface of the copper plate 1 before the lamination of the resist film thereon.

As shown in FIG. 2B, a half-etching is done to the exposed part of the copper plate 1, using a ferric chloride solution to form grooves 3 in the areas not corresponding to a predetermined wiring pattern 4. Then the resists 2 are removed using a stripping liquid, such as an NaOH solution. The depth of the grooves 3 is 50 μm, for instance.

As shown in FIG. 2C, resists 5 are selectively formed over the grooves 3 by lithography. The formation of the resists 5 is carried out the same way as for the resists 2.

As shown in FIG. 2D, a Ni film of 10 μm thickness is formed on the whole surface of the copper plate 1 by electrolytic plating or electroless plating. Then an Au film of 0.05 μm thickness is formed on the Ni film before the resists 5 are removed. In this manner, a plating film 6, comprised of an Au/Ni film, is formed on the surface of the wiring pattern 4.

As shown in FIG. 3A, solder 7a and solder 7b are printed in the areas where the semiconductor element 8a and the passive part 8b are to be mounted, respectively. Then a reflow process is performed with the semiconductor element 8a and the passive part 8b mounted in their respective predetermined positions. In this manner, the semiconductor element 9a and the passive part 8b are fixed onto the copper plate 1.

As shown in FIG. 3B, electrode terminals of the semiconductor element 8a are electrically connected to their respective predetermined positions on the plating film 6 by wire bonding. Use of gold wires as wires 9 for wire bonding can improve the reliability of their connection to the plating film 6, whose outermost surface is formed of Au.

As shown in FIG. 3C, a molded resin layer 10 of an epoxy resin for sealing the semiconductor element 8a and the passive part 8b is formed by using a transfer mold method. This also has the molded resin layer 10 fill the grooves 3 formed in the copper plate 1.

Finally, as shown in FIG. 1, a half-etching is done to the lower surface of the copper plate 1, using a ferric chloride solution, not only to make the copper plate 1 as thin as 20 μm but also to form projections 11 by exposing the molded resin layer 10 filled in the grooves 3. Note that the copper plate 1, turned into a thin film, and the plating film 6 are equivalent to the wiring layer 12.

The height of the projections 11 is 30 μm, for instance. In this manner, having part of the molded resin layer 10 function as projections 11 can simplify the structure and the manufacturing process of the circuit device 100, which in turn contributes to a reduction of manufacturing cost thereof.

Thus, the process as described above can achieve the production of a circuit device 100, according to the first embodiment shown in FIG. 1, at low cost.

### SECOND EMBODIMENT

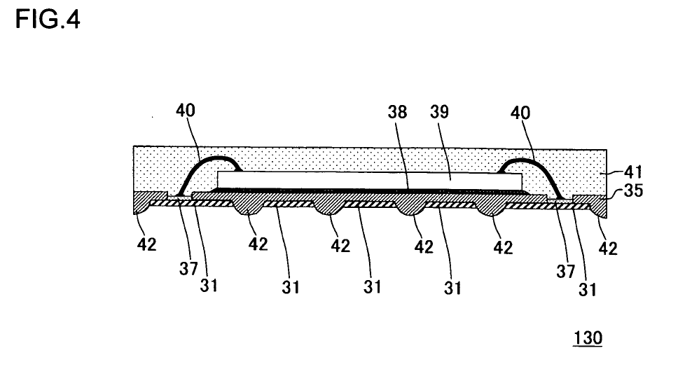

FIG. 4 is a cross-sectional view showing a structure of a circuit device according to a second embodiment of the present invention. A circuit device 130 includes a wiring layer 31, an insulation layer 35, a circuit element 39, and a molded resin layer 40.

The wiring layer 31 has a predetermined pattern formed by a conductive member. The wiring layer 31 may be formed of a single metal such as copper (Cu), but may also be formed of a plurality of metal layers. For example, forming a silver (Ag) film on top of the metal layer of copper can improve the connection reliability of wire bonding.

The insulation layer 35 is added with a filler material (not shown) which is designed to raise the thermal conductivity of the insulation layer. The material used for the insulation layer 35 is, for instance, epoxy resin, melamine derivative such as BT resin, liquid crystal polymer, PPE resin, polyimide resin, fluororesin, phenol resin, polyamidebismaleimide, or the like. The film thickness of the insulation layer 35 is not subject to any particular limitation, but is typically 25 to 60 μm. However, the lower limit of the film thickness of the insulation layer 35 must at least be larger than the particle diameter of the filler material to be discussed later.

The filler material is comprised of a particulate inorganic material which displays good thermal conductivity. The filler material may be any of alumina (Al₂O₃), silica (SiO₂), aluminum nitride (AlN), silicon nitride (SiN), and boron nitride (BN), for instance. Although the filler material according to the present embodiment is of spherical particles, the shape of the particles may be elliptical, any indeterminate form, or otherwise as long as they are particulate.

The filling rate (volumetric filling rate) of the filler in the insulation layer 35 is preferably 50 to 90 vol. %, and more preferably 65 to 75 vol. %. A filling rate of the filler lower than 50 vol. % may not provide adequate thermal conductivity. On the other hand, a filling rate of the filler higher than 90 vol. % may render the insulation layer 35 fragile, thus causing it to lose its durability. In order to achieve a filling rate of 50 to 90 vol. % filler, it is preferable to ensure a mixed presence of filler masses with relatively large particle diameters and relatively small particle diameters. In this way, particles of smaller diameters may fill in the gaps of particles of larger diameters, thus allowing the filler material to be more compactly filled in the insulation layer 35. For example, a filling rate of 70 vol. % filler can be achieved by using a mixing ratio of 1:4 for the mass A of particles of 0.7 μm average diameter and the mass B of particles of 3 μm average diameter (maximum diameter being 15 μm).

The coefficient of thermal expansion of the filler material is preferably closer to that of the wiring layer 31 than to that of the insulation layer 35. For example, if an epoxy resin (coefficient of thermal expansion: 30.3×10⁻⁶/K) is used for the insulation layer 35 and copper (coefficient of thermal expansion: 17.7×10⁻⁶/K) for the wiring layer 31, then the above relationship will be achieved by using a filler of alumina (coefficient of thermal expansion: 7.8×10⁻⁶/K) for the insulation layer 35. Use of a filler whose coefficient of thermal expansion is closer to that of the wiring layer 31 than to that of the insulation layer 35 works to hold the thermal stress between the wiring layer 31 and the filler material low even in the case when the temperature of the circuit device 130 rises. Hence, the separation of the insulation layer 35 from the wiring layer 31 is prevented.

At the bottom of the insulation layer 35, the exposed filler material filled in the insulation layer 35 is biting into the upper surface of the wiring layer 31, with the result that the wiring layer 31 is in direct contact with part of the filler material. The exposed filler material biting into the surface of the wiring layer 31 creates ups and downs on the upper surface of the wiring layer 31 resulting from the distribution of the filler material. These ups and downs increase the contact area between the wiring layer 31 and the insulation layer 35, which in turn strengthens the anchor effect. As a result, adhesion between the wiring layer 31 and the insulation layer 35 improves.

The insulation layer 35 has projections 42 protruding from the gaps in the wiring layer 31 toward the underside thereof. These projections 11, which are insulators, work as obstacles that prevent the occurrence of migration between the adjacent wiring layers 31. Moreover, even at these projections 42, the filler material contained in the insulation layer 35 is exposed, and thus the distribution of this filler material forms ups and downs on the surface of the projections 42. These ups and downs increase the surface area and improve heat radiation at the projections 42. Therefore, compared with the case without these ups and downs on the surface of the projections 42, there is an improvement of the reliability of the circuit device 130 when the temperature of the circuit element 39 rises.

The thermal conductivity of the insulation layer 35 is preferably higher than that of the molded resin layer 40. Such a condition results in a more efficient radiation of heat arising in the circuit element 39 by promoting heat diffusion through the insulation layer 35 with higher thermal conductivity as the heat radiation path. Also, the surface area of the insulation layer 35 made larger by the presence of projections 42 improves the heat radiation of the circuit device 130 as a whole.

The circuit element 39 is a semiconductor chip such as an IC (integrated circuit) or an LSI (large-scale integration circuit). The circuit element 39 is mounted in a predetermined area on the top of the insulation layer 35 through the medium of an adhesive layer 39, which is formed of an epoxy resin. Note that as the adhesive layer 38, not only an epoxy resin with insulation properties but also solder having conductivity may be used.

The molded resin layer 40 seals the circuit element 39 located above the wiring layer 31, thus protecting it against external influences. The material for the molded resin layer 40 is, for example, a thermosetting insulating resin, such as an epoxy resin. Sealing the circuit element 39 with the molded resin layer 40 can prevent the circuit element 39 and the like from getting broken or damaged at the time of operation test before the circuit device 130 is mounted, for instance.

As described above, the present embodiment can provide a highly reliable circuit device 130 at low cost because the design thereof assures an adequate level of yield.

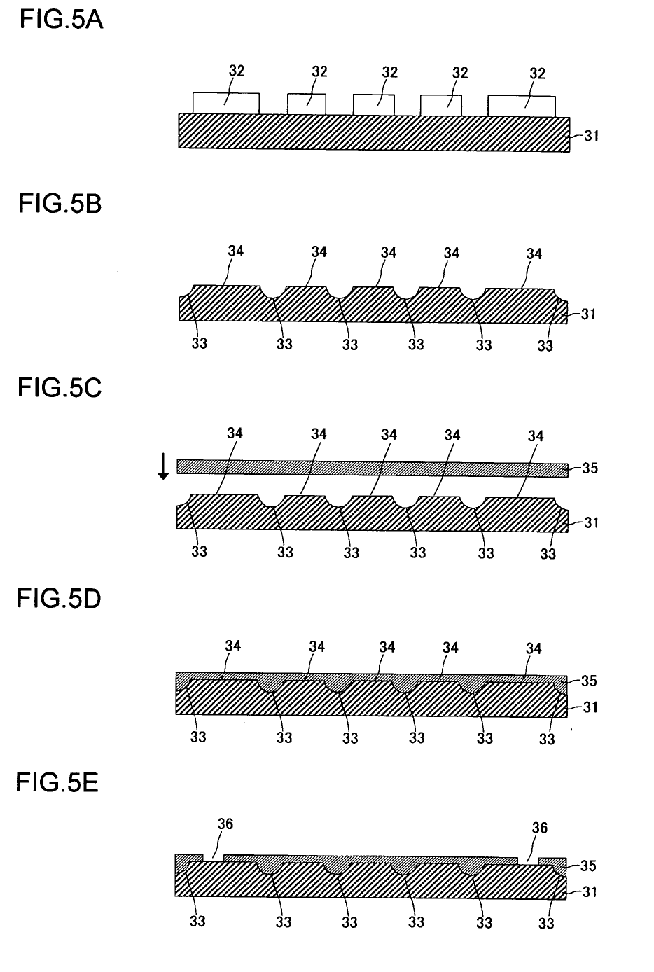

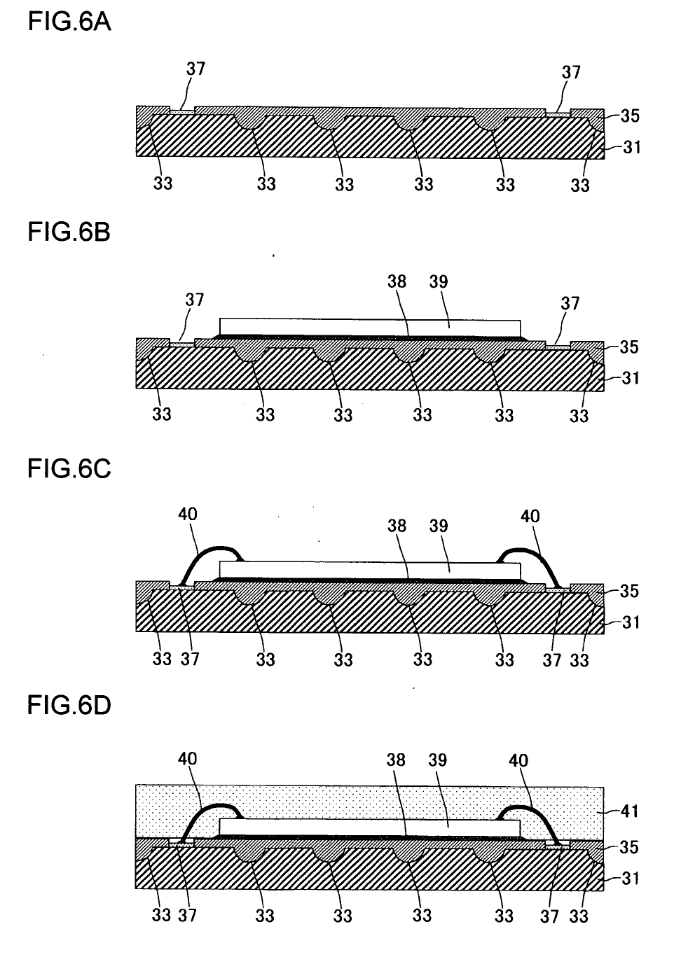

FIGS. 5A to 5E and FIGS. 6A to 6D illustrate a manufacturing method for a circuit device 130 according to the second embodiment.

Firstly, as shown in FIG. 5A, resists 32 are selectively formed according to a pattern of wiring layer on a copper plate 31 (which will be turned into a wiring layer 31 in a later process) by lithography. The film thickness of the copper plate 31 is 125 μm, for instance. More specifically, a resist film of 20 μm thickness is affixed to the copper plate 31 by a laminator unit, and it is then subjected to a UV irradiation using a photo mask having a wiring layer pattern. After this, the resists in the unexposed areas are removed by a development using an Na₂CO₃ solution, which will selectively form resists 32 on the copper plate 31. To improve the adhesion of the resists 32 to the copper plate 31, it is desirable that a pretreatment, such as grinding, cleaning and the like, be performed as appropriate on the surface of the copper plate 31 before the lamination of the resist film thereon.

As shown in FIG. 5B, a half-etching is done to the exposed part of the copper plate 31, using a ferric chloride solution to form grooves 33 in the areas not corresponding to a predetermined wiring pattern 34. Then the resists 32 are removed using a removing liquid, such as an NaOH solution. The depth of the grooves 33 is 50 μm, for instance.

As shown in FIGS. 5C and 5D, an insulation layer sheet for the insulation layer 35, containing a filler material (not shown) at a predetermined filling rate, is prepared. Note that the insulation layer sheet is formed by kneading materials at predetermined ratios after a hydrophilic treatment with a silane coupling agent is given to the surface of the filler material with the purpose of preventing the agglutination of filling materials themselves and also improve its fit to the insulation layer 35, which is an epoxy resin. This insulation layer sheet is affixed to the top of the copper plate 31 and then pressure-bonded at 150° C. for 120 minutes before it is hardened there. As a result of this pressing process, the filler material contained is exposed at the bottom of the insulation layer 35, and the insulation layer sheet is formed such that the filler material is embedded on (biting into) the surfaces of the wiring pattern 34 of the copper plate 31 and on the inner wall surfaces of the grooves 33 in the copper plate 31.

As shown in FIG. 5E, a patterning is done to the insulation layer 35, using a UV laser, to form openings 36 for wire-bonding in a later process by exposing the wiring layer 31.

As shown in FIG. 6A, an Ag film of about 10 μm thickness is formed on the exposed surface of the copper plate 31 by electrolytic plating or electroless plating. In this manner, a plating film 37, made of an Ag film, is formed on the surface of the copper plate 31.

As shown in FIG. 6B, the circuit element 39 is mounted on top of the insulation layer 35 through the medium of an adhesive layer 38 formed of an epoxy resin about 50 μm thick. The thickness of the adhesive layer 38 after the mounting of this circuit element 39 is about 20 μm. The circuit element 39 is thus fixed on the insulation layer 35. Note that as the adhesive layer 38 for fixing the circuit element 39, not only the above-mentioned material with insulation properties but also soldering material having conductivity may be used. In such a case, solder is printed in the area where the circuit element 39 is to be mounted, and then the circuit element 39, mounted in a predetermined position, is fixed by a reflow process.

As shown in FIG. 6C, electrode terminals (not shown) of the circuit element 39 are electrically connected to the plating films 37 (their respective positions of the wiring layer 31) by wire bonding. Use of gold wires as wires 40 for wire bonding can improve the reliability of their connection to the plating films 37 formed of Ag.

As shown in FIG. 6D, a molded resin layer 41 of an epoxy resin for sealing the circuit element 39 is formed by using a transfer mold method.

Finally, as shown in FIG. 4, a half-etching is done to the lower surface of the copper plate 31, using a ferric chloride solution, not only to make the copper plate 31 as thin as 20 μm but also to form projections 42 by exposing the insulation layer 35 filled in the grooves 33. The height of the projections 42 is 30 μm, for instance. Note that the ups and downs by the filler material are formed on the surfaces of the projections 42 resulting from the filler material embedded on (biting into) the inner wall surfaces of the grooves 33 in the copper plate 31.

Thus, the process as described above can achieve the production of a circuit device 130 according to the second embodiment at low cost.

Conventional circuit devices have the testing electrodes and connection electrodes provided in the same plane, with the result that the mounting area therefor tends to be larger, thus making the circuit module incorporating such circuit devices larger.

Also, the bare chips, which are not packaged, defy ready operation tests, so that the trouble of operation tests leads to increased cost. In addition to this problem, such bare chips tend to show excessive quality deterioration depending on the storage environment, thus making their distribution on the market difficult.

Furthermore, with conventional circuit devices, such as disclosed in Reference (2) in the Related Art List above, the formation of the connection electrodes on the upper surface of the package results in the thickness of the circuit device larger by the loop of the bonding wires, thus presenting an obstacle to the realization of thinner MCMs.

The third and fourth embodiments have been conceived to resolve these problems, and a general purpose thereof is to provide circuit devices with certified KGD without the larger mounting area. An advantage of the third and fourth embodiments is to provide a technology that will make it possible to supply circuit devices with certified KGD to the market. Another advantage of the third and fourth embodiments is to provide a technology that will improve the yield of MCM production.

The following items have been implemented to resolve these problems.

Item 1:

A circuit device, comprising:
   a wiring layer;
   a circuit element provided above the wiring layer;
   a molded resin layer which seals the circuit element; and
   an electrode, electrically connected with the circuit element through the wiring layer, provided in such a state as to protrude around the molded resin layer.
      Item 2:
A circuit device according to Item 1 characterized in that it includes a projection, made of insulating material, in an underside of the wiring layer.
   Item 3:
A circuit device according to Item 2, wherein the projection is part of the molded resin layer protruding from a gap in the wiring layer.
   Item 4:
A circuit device according to Item 3, wherein the electrode is provided in an area below the molded resin layer.
   Item 5:
A circuit device according to Item 4, wherein the electrode is connected to another circuit device by a wire and the height of a loop of the wire is less than or equal to the thickness of the molded resin layer.
   Item 6:
A circuit module, comprising:
   a wiring board;
   a circuit element mounted on the wiring board;
   a circuit device, according to any one of Item 1 to Item 5, provided above the circuit element; and
   a molded resin layer which seals the circuit element and the circuit device.
      Item 7:
A manufacturing method, comprising:
   forming a groove by performing a half-etching selectively a metal plate in such a manner that a wiring pattern remains;
   forming a plating film on the wiring pattern;
   mounting a circuit element on the placing film and electrically connecting the circuit element with the plating film located at a predetermined position of the wiring patter;
   filling in the groove and sealing the circuit element in a manner such that the plating film at the periphery of the wiring pattern is exposed; and
   protruding the molded resin layer filled in the groove toward an underside of the metal plate by performing a half-etching on a lower side of the metal plate.

### THIRD EMBODIMENT

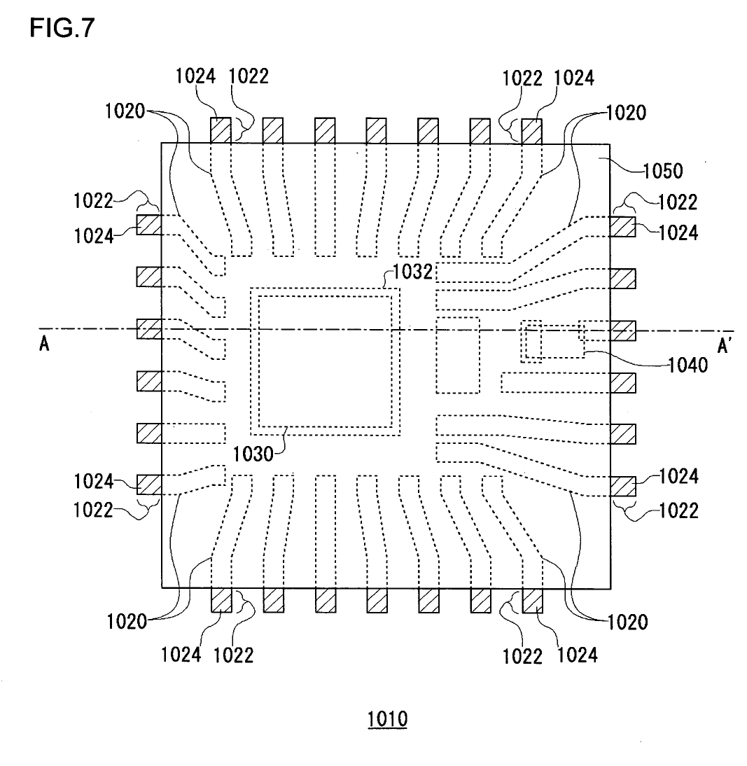

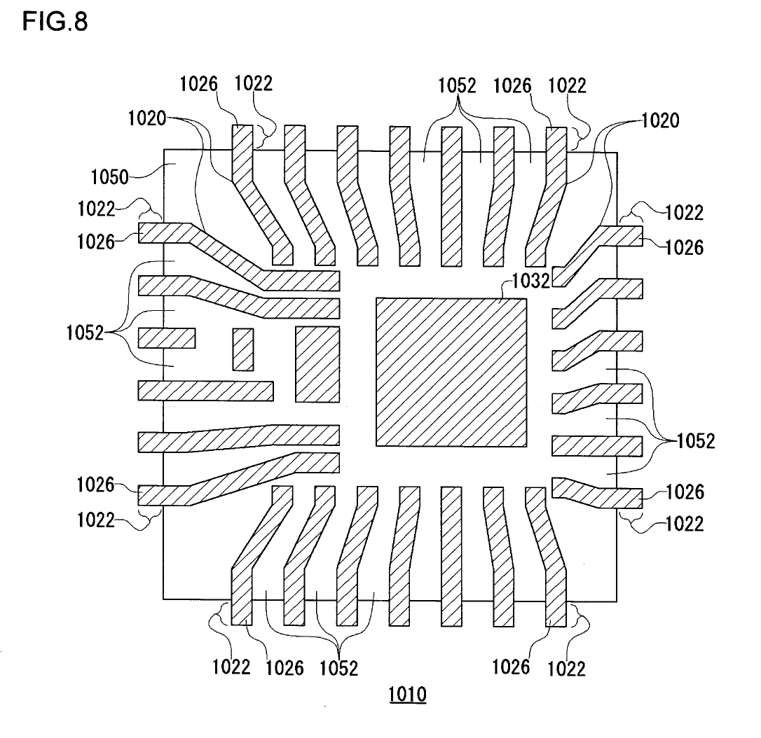

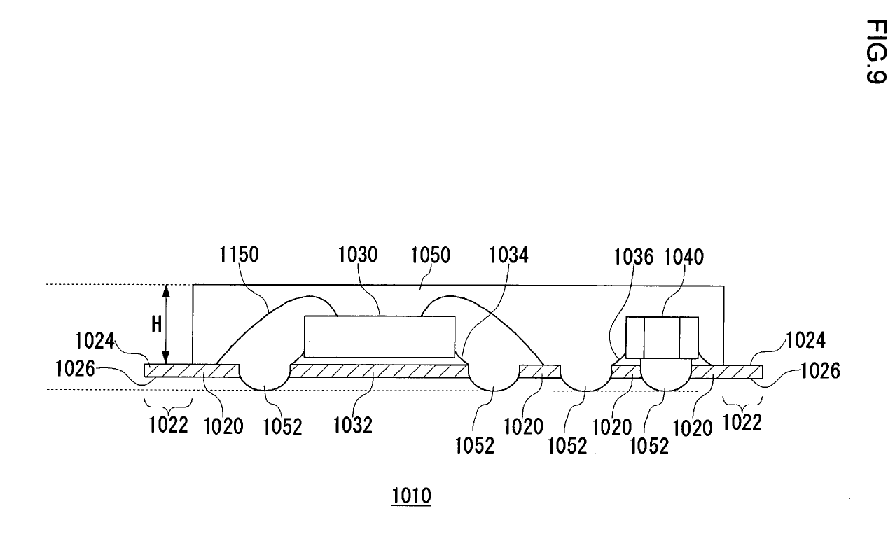

FIG. 7 and FIG. 8 are a top view and a bottom view, respectively, illustrating a structure of a circuit device 1010 according to a third embodiment. FIG. 9 is a cross-sectional view taken along the line A-A′ of the circuit device 1010 shown in FIG. 7. The circuit device 1010 includes a wiring layer 1020, a circuit element 1030, a passive part 1040, and a molded resin layer 1050.

The wiring layer 1020 has a predetermined pattern formed by a conductive member. The wiring layer 1020 may be formed of a single metal such as copper, but may also be formed of a plurality of metal layers. For example, forming an Au film on top of a copper layer through the medium of a Ni film can improve the connection reliability of wire bonding.

The circuit element 1030 is a semiconductor chip, such as an IC (integrated circuit) or an LSI (large-scale integration circuit). The circuit element 1030 is connected to the top of a metal substrate 1032, which is provided approximately in the same plane as the wiring layer 1020, via solder 1034. As with the wiring layer 1020, the metal substrate 1032 may be formed of a single metal such as copper, but may also be formed of a plurality of metal layers. Use of the same layer structure for both the metal substrate 1032 and the wiring layer 1020 can simplify the manufacturing process for the circuit device 1010. Electrode terminals of the circuit element 1030 and the wiring layer 1020 are wire-bonded to each other via wire 1150 such as gold wire.

The passive part 1040 is an electronic part, such as a capacitor, resistor, coil, or inductor. The passive part 1040 is connected to the top of the wiring layer 1020 via solder 1036 and is thus electrically connected to the wiring layer 1020.

The molded resin layer 1050 seals the circuit element 1030 and the passive part 1040 provided above the wiring layer 1020, thus protecting them against external influences. The material for the molded resin layer 1050 is, for example, a thermosetting insulating resin, such as an epoxy resin. Sealing the circuit element 1030 and the passive part 1040 with the molded resin layer 1050 can prevent the circuit element 1030 and the like from getting broken or damaged at the time of operation test before the circuit device 1010 is mounted, for instance. It also prevents changes in characteristics of the circuit element 1030 and the like caused by the storage environment of the circuit device 1010, which makes the market distribution thereof possible unlike the case with bare chips.

The molded resin layer 1050 is formed in such a way that the wiring layers 1020 at the periphery of the circuit device 1010 are exposed. In this manner, parts of the wiring layers 1020 protrude from the periphery of the molded resin layer 1050, so that the parts of the wiring layers 1020 protruding from the periphery of the molded resin layer 1050 serve as electrodes 1022. The upper surfaces of the electrodes 1022 are used as connection terminals 1024 for electrical connection with external electrode terminals. The lower surfaces of the electrodes 1022, which have equal potentials as the upper surfaces thereof, can be used as testing terminals 1026 for connection with probes or the like for testing the operation of the circuit element 1030 and/or the passive part 1040. Thus, the testing terminals 1026 provided on the back surfaces of the connection terminals 1024 solve the problem of increased mounting area for the circuit device 1010, and accordingly it is possible to make the circuit module incorporating these circuit devices 1010 smaller. Further, the possibility of operation check of the circuit device 1010 using the testing terminals 1026 makes it possible to supply the circuit device 1010 with certified KGD to the market.

Also, incorporating tested circuit devices 1010 into a circuit module (MCM) can improve the yield of the circuit module production by reducing the chances of the whole circuit module turned into a defective on account of some defective circuit elements.

The electrodes 1022 protrude from the periphery of the molded resin layer 1050 in the lower part thereof. Hence, it is possible to nullify the effect of the loop of wires on the thickness of the circuit device 1010 by holding the height of the loop of the wires connected to the connection terminals 1024 by wire bonding lower than the thickness H of the molded resin layer 1050. In this manner, the thinness of the circuit device 1010 can be realized.

The molded resin layer 1050 has projections 1052 protruding from the gaps in the wiring layer 1020 and the metal substrate 1032 toward the underside thereof.

The advantageous effects that are realized by the projections 1052 include the following:
(1) The projections 1010 support the circuit device 100 when the circuit device 1010 is placed on a stand. Thus, for instance, when the circuit device 1010 is carried on a stand for the operation test during a manufacturing process, it is possible to prevent the testing electrodes 1026 from getting damaged as they come into contact with the stand. Thus, the testing terminals 1026 are held in satisfactory condition, so that the operation test of the circuit device 1010 using the testing terminals 1026 can be performed accurately.
(2) When a circuit device 1010 is mounted on a circuit module, the projections 1052, which are insulators, create a proper gap between the wiring layer 1020 and electrode 1022 and an object to be mounted. Thus, this gap prevents the wiring layer 1020 of the circuit device 1010 from coming into contact with the other circuit in the circuit module.
(3) When a circuit device 1010 is to be mounted on another circuit device, a resin substrate, or the like, the circuit device 1010 can be positioned easily because it will not slip because of the increased surface friction produced by the projections 1052.
(4) When a circuit device 1010 is mounted on an object, the projections 1052, which function as spacers, create a proper gap between the circuit device 1010 and the object. As a result, the forces working on the circuit device 1010 when it is mounted on the object using an adhesive material will be made even, thus preventing the circuit device 1010 from tilting with the adhesive material locally pushed out.
(5) The projections 1052, which are insulators, work as obstacles that prevent the occurrence of migration between the wiring layers 12.

Method for Manufacturing a Circuit Device

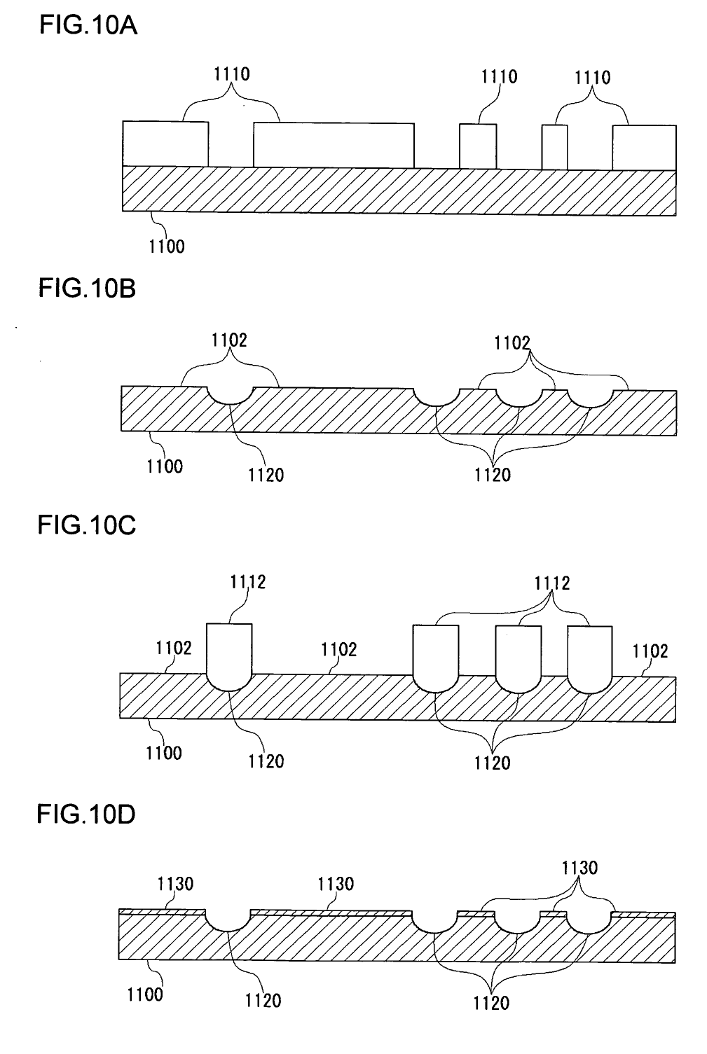

Firstly, as shown in FIG. 10A, resists 1110 are selectively formed according to a pattern of wiring layer on a copper plate 1100 by lithography. The film thickness of the copper plate 1100 is 125 μm, for instance. More specifically, a resist film of 20 μm thickness is affixed to the copper plate 1100 by a laminator unit, and it is then subjected to a UV irradiation using a photo mask having a wiring layer pattern. After this, the resists in the unexposed areas are removed by a development using a Na₂CO₃ solution, which will selectively form resists 1110 on the copper plate 1100. To improve the adhesion of the resists 1110 to the copper plate 1100, it is desirable that a pretreatment, such as grinding, cleaning and the like, be performed as appropriate on the surface of the copper plate 1100 before the lamination of the resist film thereon.

As shown in FIG. 10B, a half-etching is done to the exposed part of the copper plate 1100, using a ferric chloride solution to form grooves 1120 in the areas not corresponding to a predetermined wiring pattern 1102 Then the resists are removed using a stripping agent, such as an NaOH solution. The depth of the grooves 1120 is 50 μm, for instance.

As shown in FIG. 10C, resists 1112 are selectively formed over the grooves 1120 by lithography. The formation of the resists 1120 is carried out the same way as for the resists 1110.

As shown in FIG. 10D, a Ni film of 10 μm thickness is formed on the whole surface of the copper plate 1100 by electrolytic plating or electroless plating. Then an Au film of 0.05 μm thickness is formed on the Ni film before the resists 1112 are removed. In this manner, a plating film 1130, comprised of an Au/Ni film, is formed on the surface of the wiring pattern 1102.

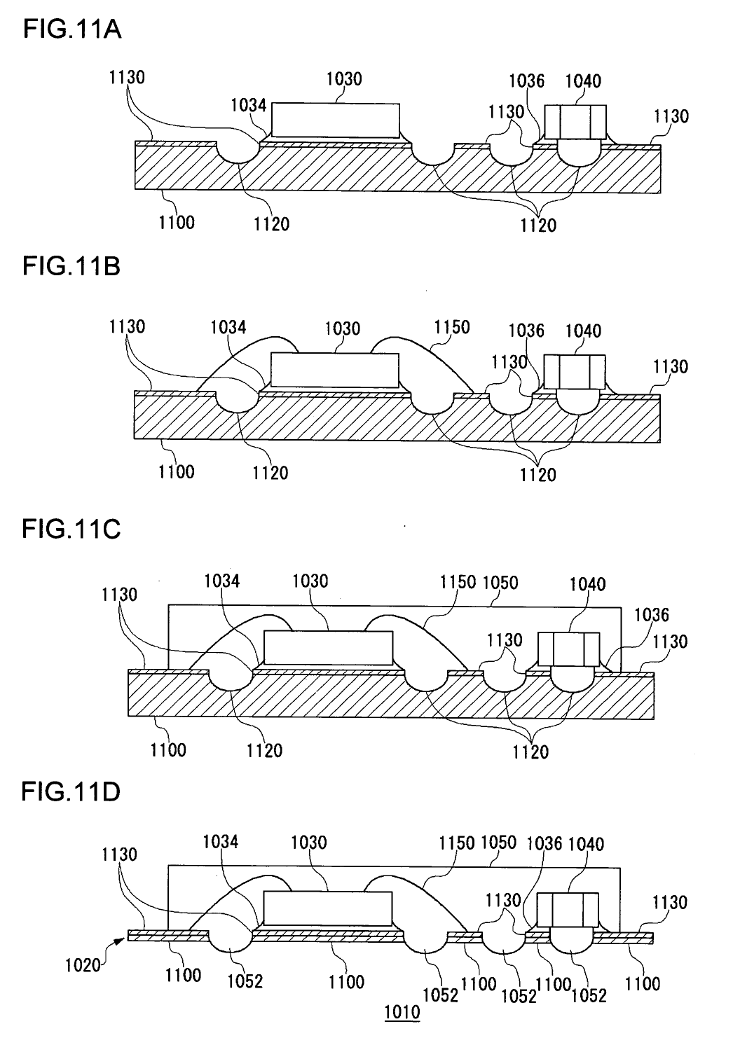

As shown in FIG. 11A, solder 1034 and solder 1036 are printed in the areas where the a circuit element 1030 and a passive part 1040 are to be mounted, respectively. Then a reflow process is performed with the circuit element 1030 and the passive part 1040 mounted in their respective predetermined positions. In this manner, the circuit element 1030 and the passive part 1040 are fixed onto the copper plate 1100.

As shown in FIG. 11B, electrode terminals of the circuit element 1030 are electrically connected to their respective predetermined positions on the plating film 1130 by wire bonding. Use of gold wires as wires 1150 for wire bonding can improve the reliability of their connection to the plating film 1130, whose outermost surface is formed of Au.

As shown in FIG. 11C, a molded resin layer 1050 of an epoxy resin for sealing the circuit element 1030 and the passive part 1040 is formed by using a transfer mold method. At this time, the molded resin layer 1050 partially covers the copper plate 1100, and the plating film 1130 at the periphery of the copper plate 1100 is exposed. As a result, the exposed plating film 1130 can be used as connection terminals 1024 for connection with external electrode terminals. This also has the molded resin layer 10 fill the grooves 1120 formed in the copper plate 1100.

Then, as shown in FIG. 11D, a half-etching is done to the lower surface of the copper plate 1100, using a ferric chloride solution, not only to make the copper plate 1100 as thin as 20 μm but also to form projections 1052 by exposing the molded resin layer 1050 filled in the grooves 1120. Note that the copper plate 1100, turned into a thin film, and the plating film 1130 are equivalent to the wiring layer 1020 shown in FIG. 9. The exposed parts not covered by the molded resin layer 1050, as shown in FIG. 9, serve as electrodes 1022, the upper surface of which being used as connection terminals 1024 and the lower surface of which being used as testing terminals 1026.

The height of the projections 1052 is 30 μm, for instance. In this manner, having part of the molded resin layer 10 function as projections 1052 can simplify the structure and the manufacturing process of the circuit device 1010, which in turn contributes to a reduction of manufacturing cost thereof. Thus, the process as described above can achieve the production of a circuit device 1010, according to the third embodiment shown in FIG. 7 to FIG. 9, at low cost.

### FOURTH EMBODIMENT

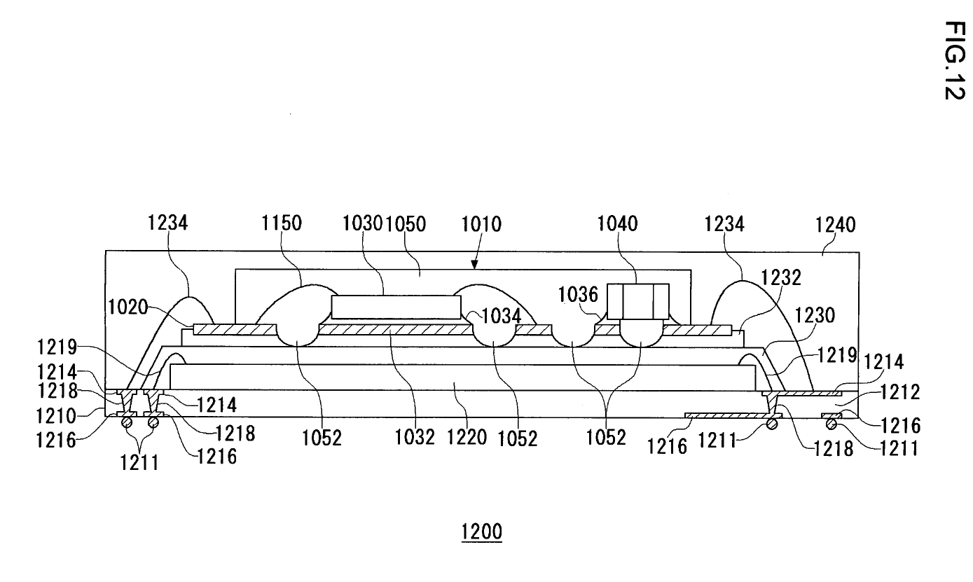

FIG. 12 is a cross-sectional view showing a structure of a circuit module 1200 according to a fourth embodiment. The circuit module 1200 is an MCM which incorporates a plurality of circuit elements including a circuit device 1010 according to the third embodiment. The circuit module 1200 includes a multilayer board 1210, a circuit element 1220, a molded resin layer 1230, a circuit device 10 according to the third embodiment, and a molded resin layer 1240.

The multilayer board 1210 is provided with a wiring layer 1214 and a wiring layer 1216 respectively on the upper surface and the lower surface thereof with the medium of an interlayer insulation film 1212 in between. The wiring layer 1214 and the wiring layer 1216 are electrically connected to each other by a via plug 1218 penetrating the interlayer insulation film 1212. The interlayer insulation film 1212 is formed of an epoxy resin, for instance, whereas the wiring layer 1214, the wiring layer 1216, and the via plug 1218 are formed of copper, for instance. A plurality of solder balls 1211 are affixed in an array to the lower surface of the multilayer board 1210.

A circuit element 1220 is a semiconductor chip, such as an IC (integrated circuit) or an LSI (large-scale integration circuit). The circuit element 1220 is mounted on the multilayer board 1210 by use of an adhesive, and electrode terminals provided on the circuit element 1220 are wire-bonded to the wiring layer 1214 by wires 1219 such as gold wires.

The molded resin layer 1230 is an insulation resin for sealing the circuit element 1220. The molded resin layer 1230 protects the circuit element 1220 against external influences. The molded resin layer 1230 partially covers the multilayer board 1210. The parts of the wiring layer 1214 not covered by the molded resin layer 1230 are formed as electrode terminals for electrically connecting the circuit device 1010.

The circuit device 1010 is mounted on the molded resin layer 1230 through the medium of an under-fill material 1232. The circuit device 1010, which is a KGD whose operation has been certified using the testing terminal 1026, improves the fabrication yield of the circuit module 1200. It is preferable that at least the projections 1052 on the periphery, of the projections 1052 provided in the lower part of the circuit device 1010, are in contact with the molded resin layer 1230. By such an arrangement, the circuit device 1010 can be mounted properly on the molded resin layer 1230 without tilting the circuit device 1010.

As described previously, the connection terminals 1024 of the circuit device 1010 are wire-bonded to the electrode terminals provided in the parts not covered by the molded resin layer 1230, with wires 1234, such as gold wires. In this arrangement, connection with the circuit element 1220 can be made in an area array by rewiring the necessary wiring for the circuit device 1010 at the multilayer board 1210, so that the mounting area can be smaller than the case with the conventional lead frame mounting.

The whole of the molded resin layer 1230 and the circuit device 1010 is covered by the molded resin layer 1240. Thus the molded resin layer 1240 protects the circuit device 1010 and the circuit element 1220 from external influences more reliably.

A Method for Manufacturing a Circuit Module

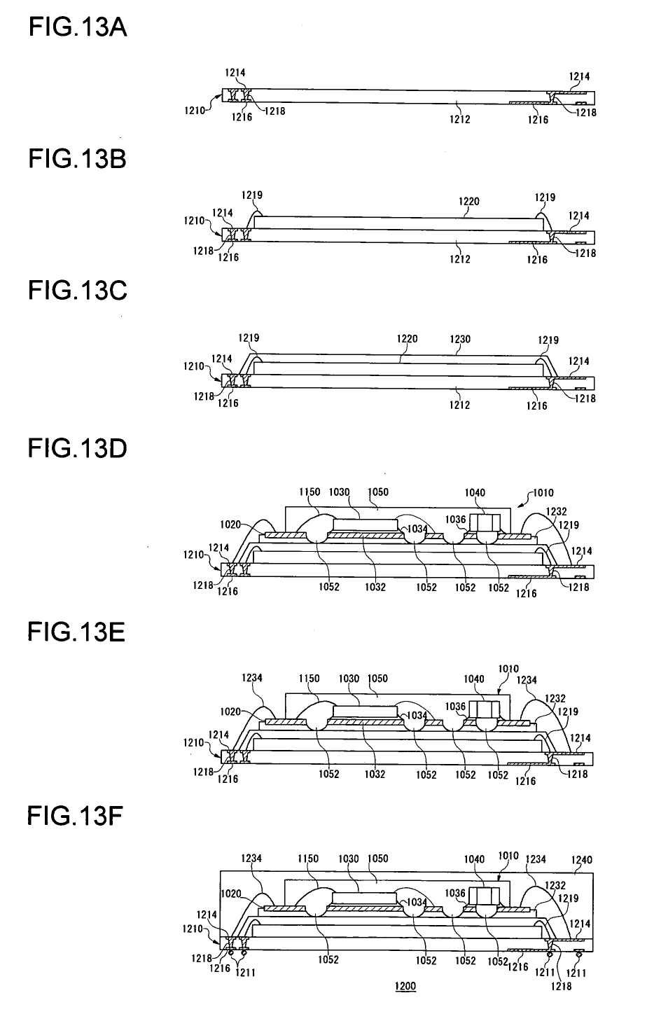

A manufacturing process for a circuit module according to the fourth embodiment will be described with reference to FIGS. 13A to 13F. Firstly, a multilayer board 1210 as shown in FIG. 13A is prepared. The multilayer board 1210 has a multilayer structure in which a wiring layer 1214 and a wiring layer 1216 are stacked with the medium of an interlayer insulation film 1212, and the wiring layer 1214 and the wiring layer 1216 are electrically connected to each other via a via plug 1218.

Next, as shown in FIG. 13B, a circuit element 1220 is mounted on the multilayer board 1210 with the medium of an adhesive (not shown) or the like. Then the electrode terminals of the circuit element 1220 and the electrode terminals provided on the wiring layer 1214 are wire-bonded to each other using wires 1219 such as gold wires.

Then, as shown in FIG. 13C, the circuit element 1220 is sealed with a molded resin layer 1230, which is formed of a thermosetting insulation resin like an epoxy resin, using a transfer mold method. At this time, the sealing is carried out such that the electrode terminals for the circuit device 1010 provided on the wiring layer 1214 are not covered by the molded resin layer 1230. A burn-in is carried out after the formation of the molded resin layer 1230. To put it more specifically, by heating the circuit element 1220, an inspection is made to see if any initial faults develop with the circuit element 1220.

Then, as shown in FIG. 13D, an under-fill material 1232 is applied on the molded resin layer 1230, and then the circuit device 1010 finished with KGD certification is mounted. At this time, an arrangement is made to have at least the projections 1052 on the periphery, of the projections 1052 provided in the lower part of the circuit device 1010, come in contact with the molded resin layer 1230, so that the circuit device 1010 can be mounted properly on the molded resin layer 1230 without tilting the circuit device 1010.

Next, as shown in FIG. 13E, the electrode terminals of the circuit device 1010 and the electrode terminals for use with the circuit device 1010 provided in the wiring layer 1214 are wire-bonded to each other by use of wires 1234 such as gold wires.

Then, as shown in FIG. 13F, the circuit device 1010, the molded resin layer 1230, and the like are collectively sealed with a thermosetting insulation resin such as an epoxy resin. Following this, solder balls 1211 for electrical connection of the circuit module to the packaging object are joined to the lower surface of the multilayer board 1210.

It is to be noted that the solder balls 1211 need to be melted when the circuit module 1200 is mounted. At this time, if both the solder 1034 and solder 1036 within the circuit module 1200 are melted, the reliability of electrical connection may sometimes be compromised. Hence, it is preferable that the melting point of the solder 1034 and solder 1036 be higher than that of the solder balls 1211. In view of this requirement, Sn-0.7 Cu (melting point: 227° C.), Sn (melting point: 232° C.), or the like may be used as the solder 1034 and solder 1036, and Sn-3 Ag-0.5 Cu (melting point: 217° C.), Sn-1.5 Ag-0.5 Cu (melting point: 217° C.), or the like may be used as the solder of the solder balls 1211.

The present invention is not limited to the above-described embodiments, and it is understood by those skilled in the art that various modifications such as changes in design may be made based on their knowledge and the embodiments added with such modifications are also within the scope of the present invention.

For example, in the circuit module 1200 according to the fourth embodiment, the circuit element 1220 is sealed by the molded resin layer 1230 and the circuit device 1010 is mounted on the molded resin layer 1230. However, a bare chip may be used as the circuit element 1220, and the circuit device 1010 may be mounted directly on the circuit element 1220.

Also, the circuit module 1200 according to the fourth embodiment is of a two-tier stack structure of a circuit element 1220 and a circuit device 1010. However, it may be made a three-tier stack structure by preparing two or more circuit devices 1010 and stacking other circuit devices 1010 on a circuit device 1010.

While the preferred embodiments of the present invention have been described using specific terms, such description is for illustrative purposes only, and it is to be understood that changes and variations may be made without departing from the spirit or scope of the appended claims.

What is claimed is:

1. A circuit device, comprising:
a wiring layer;
a circuit element provided above said wiring layer; and
a molded resin layer which seals said circuit element, wherein there are provided projections, made of insulating material, which protrude from gaps in said wiring layer toward an underside of said wiring layer.

2. A circuit device according to claim 1, wherein the projection is part of said molded resin layer.

3. A circuit device according to claim 1, further comprising an insulation layer provided between said wiring layer and said circuit element,
wherein the projection is part of said insulation layer and the thermal conductivity of said insulation layer is higher than that of said molded resin layer.

4. A circuit device according to claim 3, wherein said insulation layer includes a particulate filler material, and
wherein part of the particulate filler material in the projection of said insulation layer is exposed.
